(19) United States
(12) Patent Application Publication
(10) Pub. No.: US 2026/0040746 A1
(43) Pub. Date: Feb. 5, 2026

(54) DISPLAY APPRATUS

(71) Applicant: LG Display Co., Ltd., Seoul (KR)

(72) Inventors: Changwoo CHUN, Paju-si (KR); Giyoun KIM, Paju-si (KR)

(73) Assignee: LG Display Co., Ltd., Seoul (KR)

(21) Appl. No.: 19/246,039

(22) Filed: Jun. 23, 2025

(30) Foreign Application Priority Data
Aug. 1, 2024 (KR) 10-2024-0102378

(51) Int. Cl. H10H 29/853

(52) U.S. Cl. CPC H10H 29/853

(57) ABSTRACT

A display apparatus according to one embodiment of the present disclosure includes a panel support layer, a display panel disposed on the panel support layer, a panel cover layer disposed on the display panel, and a first cover layer disposed on the panel cover layer. The first cover layer has a greater modulus than the panel cover layer. By arranging the cover layers in this manner, with varying mechanical properties, the display apparatus can achieve improved flexibility and durability. This configuration enables the apparatus to bend or stretch while reducing the risk of damage to the display panel or internal components.

### CROSS REFERENCE TO RELATED APPLICATION

The present application claims priority to Korean Patent Application No. 10-2024-0102378, filed Aug. 1, 2024, the entire contents of which is incorporated herein for all purposes by this reference.

### BACKGROUND

### Technical Field

The present disclosure relates to a display apparatus.

### Description of the Related Art

As the information society develops, various demands for display apparatuses for displaying images are increasing, and various types of display apparatuses, such as a liquid crystal display (LCD) apparatus and an organic light-emitting diode (OLED) display apparatus, are being utilized.

The scope of application of display apparatuses is becoming more diverse from computer monitors and TVs to personal portable devices, and research on display apparatuses with a large active area and reduced volume and weight is being conducted.

In addition, stretchable display apparatuses, which are manufactured by forming a display unit, lines, etc., on a flexible substrate, such as plastic that is a flexible material, or the like, to be stretched in a specific direction and changed into various shapes, are attracting attention as next-generation display apparatuses.

### BRIEF SUMMARY

The disclosed display apparatus includes a multilayer cover structure in which the modulus increases progressively in layers farther from the display panel. This structural arrangement enables the apparatus to bend and stretch smoothly while reducing the risk of damage to internal circuits. Each cover layer is designed to fulfill a specific function, such as enhancing surface durability, protecting touch sensors, or supporting the display panel, which contributes to improved mechanical stability and device reliability. The design incorporates rigid regions embedded within a flexible base and connected by curved or patterned flexible substrates, allowing the device to deform without compromising electrical performance.

The display apparatus further includes metal circuit lines placed only in rigid regions, with flexible interconnects bridging the gaps, thereby preventing mechanical stress during deformation. Adhesive layers with different mechanical properties are selectively applied, including those formed by inkjet methods, to support structural stability under repeated stretching. The design also supports integration with micro light-emitting diodes and thin film transistors. These features make the apparatus suitable for use in wearable electronics, flexible smart devices, and displays that can conform to curved or irregular surfaces.

For example, various embodiments of the present disclosure is directed to providing a display apparatus that can be smoothly bent or stretched without being damaged by arranging cover layers having different moduli.

The present disclosure is also directed to providing a display apparatus in which, by arranging cover layers having different moduli it is possible to suppress or prevent damage to a circuit element even when the display apparatus is bent or stretched.

The present disclosure is also directed to providing a display apparatus in which, by arranging a plurality of cover layers having different moduli and functions, it is possible to secure a stretch ratio and secure surface characteristics and durability.

Technical benefits of the present disclosure are not limited to the above-described benefits, and other technical benefits may be inferred from the following embodiments.

According to one embodiment of the present disclosure, there is provided a display apparatus including a panel support layer, a display panel disposed on the panel support layer, a panel cover layer disposed on the display panel, and a first cover layer disposed on the panel cover layer and having a greater modulus than the panel cover layer.

According to another embodiment of the present disclosure, there is provided a display apparatus including a first cover layer, a second cover layer disposed on the first cover layer, a third cover layer disposed on the second cover layer, a display panel disposed on the third cover layer, and a fourth cover layer disposed on the display panel, in which a modulus of each of the first cover layer, the second cover layer, the third cover layer, and the fourth cover layer increases in a direction away from the display panel.

Detailed matters of other embodiments are included in the detailed description and accompanying drawings.

According to the embodiments of the present disclosure, it is possible to provide the display apparatus that can be smoothly bent or stretched without being damaged even when being bent or stretched.

According to the embodiments of the present disclosure, even when the display apparatus is bent or stretched, it is possible to suppress or prevent damage to the circuit element and improve reliability.

According to the embodiments of the present disclosure, it is possible to secure the stretch ratio and secure surface characteristics and durability.

According to the embodiments of the present disclosure, it is possible to increase the life of the display apparatus, thereby reducing power consumption of the display apparatus.

However, effects obtainable from the present disclosure are not limited to the above-described effects, and other effects that are not mentioned will be able to be clearly understood by those skilled in the art to which the present disclosure pertains based on the following description.

### BRIEF DESCRIPTION OF THE SEVERAL VIEWS OF THE DRAWINGS

FIGS. 1 and 2 are perspective views of a display apparatus according to one embodiment.

FIG. 3 is an exploded perspective view of the display apparatus according to one embodiment.

FIG. 4 is a cross-sectional view of the display apparatus according to one embodiment.

FIG. 5 is an exemplary cross-sectional view of the display apparatus according to one embodiment.

FIG. 6 is an enlarged plan view illustrating the display apparatus according to one embodiment.

FIG. 7 is a cross-sectional view of one pixel of the display apparatus according to one embodiment.

FIG. 8 is a cross-sectional view of a display apparatus according to another embodiment.

FIG. 9 is a cross-sectional view of a display apparatus according to still another embodiment.

### DETAILED DESCRIPTION

Hereinafter, embodiments will be described with reference to the accompanying drawings. In the present disclosure, when a certain component (or an area, a layer, a portion, etc.) is described as being “on,” “connected,” or “coupled to” another component, it means that the certain component may be directly connected/coupled to another component or a third component may be disposed therebetween.

To elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The same reference numerals indicate the same components. In addition, in the drawings, thicknesses, proportions, and dimensions of components are exaggerated for effective description of technical contents. The term “and/or” includes all one or more combinations that may be defined by the associated components.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular includes the plural unless the context clearly dictates otherwise.

Terms such as “under,” “at a lower side,” “above,” and “at an upper side” are used to describe the associated relationship between the components illustrated in the drawings. The terms are relative concepts and are described with respect to directions marked in the drawings.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

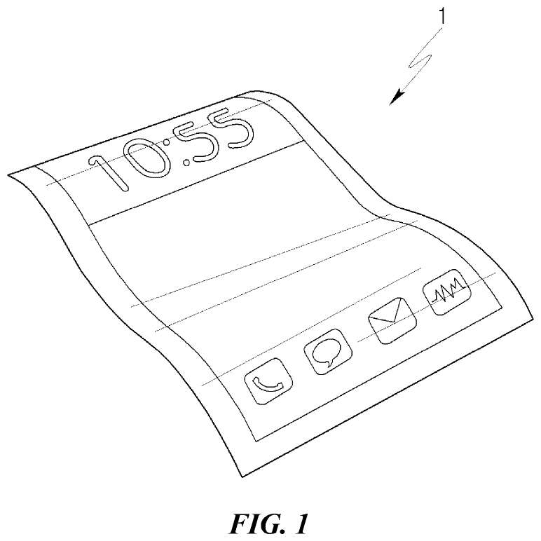

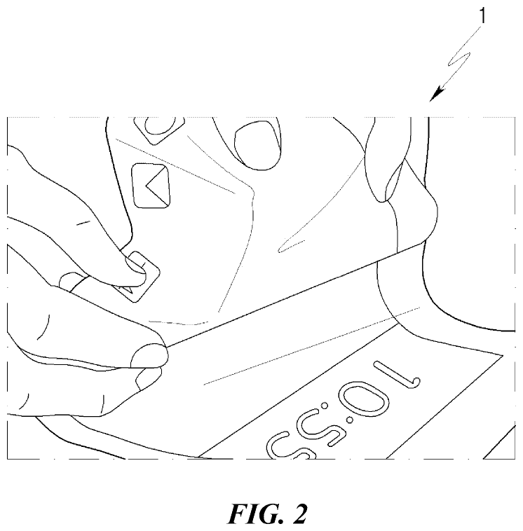

FIGS. 1 and 2 are perspective views of a display apparatus according to one embodiment.

Referring to FIGS. 1 and 2, a display apparatus 1 is a stretchable display apparatus and may be changed or deformed to various forms. For example, the display apparatus 1 may be deformed in shape, such as being bent in a plurality of areas, bent in the plurality of areas with respect to axes extending in different directions, or deformed by external pressure. However, the embodiments of the present disclosure are not limited thereto.

Even when the display apparatus 1 is bent or deformed in shape, the display apparatus may display a screen on a portion in which the shape is deformed. However, the embodiments of the present disclosure are not limited thereto, and for example, touch sensing may be performed on the portion in which the shape is deformed, or various inputs may be made by the deformed shape.

For example, the stretchable display apparatus may be freely deformed in any form, such as stretching, folding, twisting, or the like, and thus may be a free-form display apparatus.

For example, the stretchable display apparatus may be thin and light and adhered to curved surfaces, such as skin, clothing, etc. Accordingly, the stretchable display apparatus may be applied to various industrial fields, such as wearables, mobility, smart devices, gaming, fashion, etc. In addition, since the stretchable display apparatus can enable an era of IT devices that can be worn like clothes or attached to the body, the stretchable display apparatus may be a display apparatus capable of changing daily life.

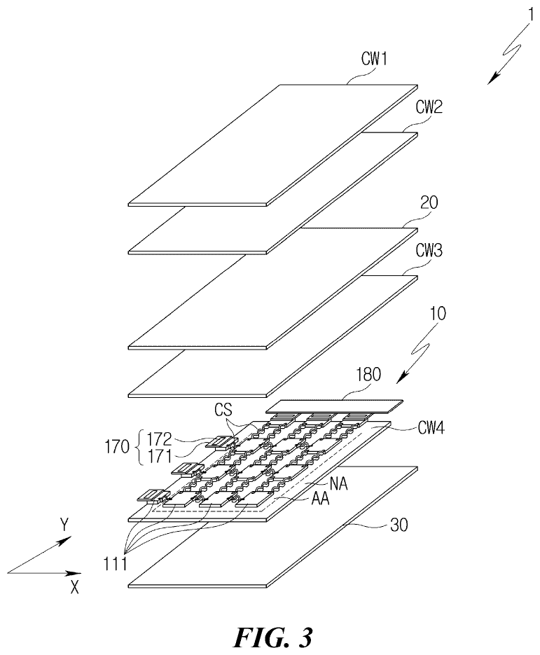

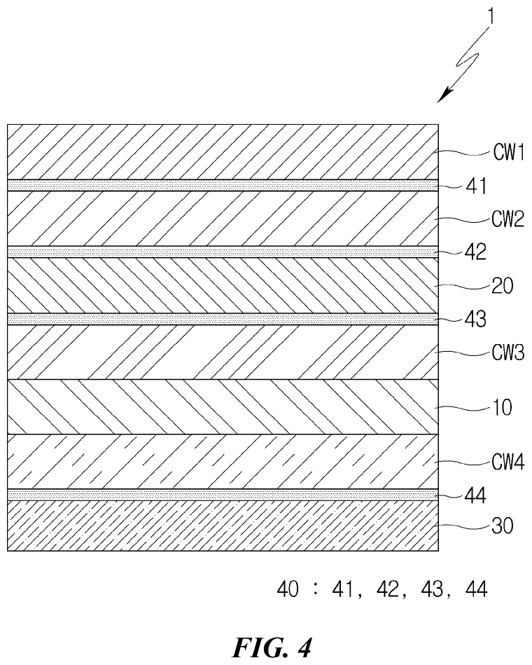

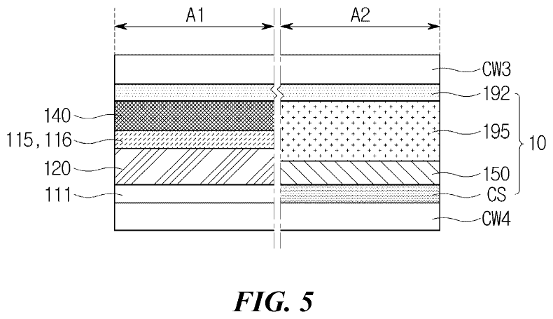

FIG. 3 is an exploded perspective view of the display apparatus according to one embodiment. FIG. 4 is a cross-sectional view of the display apparatus according to one embodiment. FIG. 5 is an exemplary cross-sectional view of the display apparatus according to one embodiment. FIG. 5 exemplarily illustrates a structure of an active area of the display apparatus 1.

Referring to FIGS. 3 to 5, the display apparatus 1 may include a first cover layer CW1, a second cover layer CW2 (or a touch cover layer) disposed below the first cover layer CW1, a touch layer 20 disposed below the second cover layer CW2, a third cover layer CW3 (or a panel cover layer) disposed below the touch layer 20, a display panel 10 disposed under the third cover layer CW3, a fourth cover layer CW4 (or a panel support layer) disposed below the display panel 10, and a back cover 30 disposed below the fourth cover layer CW4.

The display apparatus 1 may further include at least one support substrate 111, at least one connection substrate CS, a connection film 170, a printed circuit board 180, and an adhesive layer 40 (41, 42, 43, and 44) disposed between the members.

The display apparatus 1 may be a stretchable display apparatus, and a stretchable display apparatus will be described below as an example.

At least some of the first to fourth cover layers CW 1 to CW4 may have different moduli. The first to fourth cover layers CW1 to CW4 may have a greater modulus in a direction away from the display panel 10.

A modulus of the first cover layer CW1 may be greater than a modulus of the second cover layer CW2, the modulus of the second cover layer CW2 may be greater than a modulus of the third cover layer CW3, and the modulus of the third cover layer CW3 may be equal to a modulus of the fourth cover layer CW4.

The fourth cover layer CW4 is a substrate for supporting and protecting various components of the display apparatus 1 and may be a first substrate (or a lower substrate). The fourth cover layer CW4 may provide a space in which the display panel 10 may be disposed.

The fourth cover layer CW4 is a flexible substrate and may be formed of a bendable or stretchable insulation material. For example, the fourth cover layer CW4 may be formed of an elastomer, such as silicon rubber of polydimethylsiloxane (PDMS), polyurethane (PU), polytetrafluoroethylene (PTFE), etc., and thus may be flexible. However, the material of the fourth cover layer CW4 is not limited thereto.

A modulus of the fourth cover layer CW4 may range from 0.1 MPa to 1.5 MPa, preferably, may range from 0.5 MPa to 1.0 MPa.

When the modulus of the fourth cover layer CW4 is smaller than the above range, a problem in a process that the fourth cover layer CW4 may not be smoothly fixed or a problem that the display panel 10 may not be smoothly supported and protected may occur.

When the modulus of the fourth cover layer CW4 is greater than the above range, problems that the resistance of a circuit of the display panel 10 increases, the circuit is short-circuited, etc., may occur.

Specifically, due to the stretching and recovery of the stretchable display apparatus 1, lines formed of a metal, such as a connection line 150, may be deformed in a thickness direction. In this case, when the modulus of the fourth cover layer CW4 is greater than the above range, a large stress may be applied to the deformed lines formed of a metal, such as the connection line 150, and thus the lines formed of a metal, such as the connection line 150, may have increased resistance or may be short-circuited.

Accordingly, when the modulus of the fourth cover layer CW4 falls within the above range, it is possible to protect and support the display panel 10 and suppress or prevent defects that may occur in the lines formed of a metal, such as the connection line 150, due to stretching, recovery, etc., of the stretchable display apparatus 1, thereby improving the reliability of the display panel 10.

A thickness of the fourth cover layer CW4 may range from 300 μm (micrometers) to 350 μm.

When the thickness of the fourth cover layer CW4 is smaller than the above range, design and formation may be difficult in terms of process. When the thickness of the fourth cover layer CW4 is greater than the above range, the modulus of the fourth cover layer CW4 may increase, which may apply a large stress to the deformed lines formed of a metal, such as the connection line 150.

Accordingly, when the thickness of the fourth cover layer CW4 falls within the above range, the fourth cover layer CW4 can be smoothly designed and produced in terms of process, and it is possible to suppress or prevent defects that may occur in the lines formed of a metal, such as the connection line 150, due to stretching, recovery, etc., of the stretchable display apparatus 1, thereby improving the reliability of the display panel 10.

A transmittance of the fourth cover layer CW4 may be 90% or more, a haze of the fourth cover layer CW4 may be 1% or less, a yellow index (YI) may be 2 or less, and a stretch ratio may be 40% or more and 100% or less.

The fourth cover layer CW4 may include an active area AA and a non-active area NA surrounding the active area AA. The active area AA is an area in which an image is displayed in the display apparatus 1, and display elements and various driving elements for driving the display elements may be disposed in the active area AA. The active area AA may include a plurality of pixels, each of which includes a plurality of sub-pixels.

The plurality of pixels may be disposed in the active area AA and may include a plurality of display elements. Each of the plurality of sub-pixels may be connected to various lines. For example, each of the plurality of sub-pixels may be connected to various lines, such as a gate line, a data line, a high-potential voltage line, a low-potential voltage line, a reference voltage line, etc.

The non-active area NA may be an area adjacent to the active area AA. The non-active area NA may surround or adjacent to the active area AA, but is not limited thereto. The non-active area NA is an area in which an image is not displayed, and lines, circuit units, etc., may be formed in the non-active area NA. For example, a plurality of pads may be disposed in the non-active area NA, and each pad may be connected to each of the plurality of sub-pixels in the active area AA.

At least one support substrate 111 may be disposed on the fourth cover layer CW4. The support substrates 111 are rigid substrates and may be independently disposed to be spaced apart from each other on the fourth cover layer CW4. The support substrate 111 may have a higher rigidity than the fourth cover layer CW4. For example, the fourth cover layer CW4 may have a softer characteristic than the support substrate 111, and the support substrate 111 may have higher rigid characteristics than the fourth cover layer CW4.

For example, the support substrate 111 may be formed of a flexible plastic material. For example, the support substrate 111 may be formed of polyimide (PI), polyacrylate, polyacetate, etc.

A modulus of the support substrate 111 may be higher than the modulus of the fourth cover layer CW4. The modulus is an elastic coefficient that represents a ratio of deformation due to stress applied to a substrate, and, for example, when the modulus is relatively high, hardness may be relatively high. Accordingly, the support substrate 111 may be a plurality of rigid substrates having a higher rigidity than the fourth cover layer CW4. The modulus of the support substrate 111 may be 1000 times greater than the modulus of the fourth cover layer CW4, but is not limited thereto.

The embodiments of the present disclosure are not limited thereto, but, in some embodiments, the fourth cover layer CW4 may include a plurality of first lower patterns and a second lower pattern. The plurality of first lower patterns may be disposed in an area of in the fourth cover layer CW4, which overlaps the support substrate 111, and the second lower pattern may be disposed in the entire area excluding the area in which the support substrate 111 is disposed or disposed in the entire area of the display apparatus 1.

In this case, moduli of the plurality of first lower patterns may be greater than a modulus of the second lower pattern. For example, the plurality of first sub-patterns may be formed of the same material as the support substrate 111, and the second sub-pattern may be formed of a material having a smaller modulus than the support substrate 111.

A plurality of connection substrates CS may be disposed between the support substrates 111. The plurality of connection substrates CS are substrates that connect adjacent support substrates 111 and may be third substrates. The plurality of connection substrates CS may be formed of the same material as the support substrate 111 and formed integrally with the support substrate 111 at the same time, but are not limited thereto.

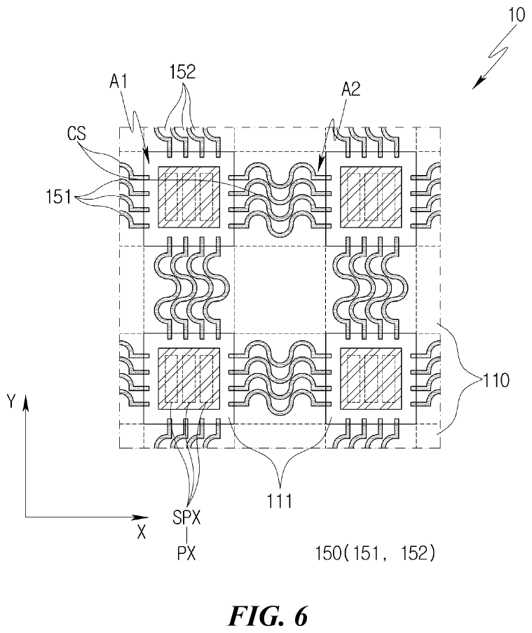

The plurality of connection substrates CS may have a curved shape. For example, as illustrated in FIG. 6, the plurality of connection substrates CS may have a sine wave shape. The shape of the plurality of connection substrates CS is not limited thereto. For example, the plurality of connection substrates CS may extend in a zigzag shape or have various shapes, such as a plurality of rhombus-shaped substrates being connected at vertices and extending, etc. In addition, the number and shape of plurality of connection substrates CS illustrated in FIG. 6 are exemplary, and the number and shape of plurality of connection substrates CS may be changed in various ways according to a design and are not limited thereto.

The connection film 170 is a film in which various components are disposed on a flexible base film 171 and may be a component for supplying signals to the plurality of sub-pixels of the active area AA. The connection film 170 may be bonded or connected to a plurality of pads disposed in the non-active area NA and may supply a power voltage, a data voltage, a gate voltage, etc., to each of the plurality of sub-pixels of the active area AA through the pads. The connection film 170 may include the base film 171 and a driving IC 172, and various components may be disposed in addition to the above components.

The base film 171 may be a layer that supports the driving IC 172 of the connection film 170. The base film 171 may be formed of an insulation material and, for example, may be formed of a flexible insulation material.

The driving IC 172 may be a component for processing data for displaying an image and a driving signal for processing the data. FIG. 3 illustrates the driving IC 172 mounted by a chip on film (COF) method, but the embodiments of the present disclosure are not limited thereto, and the driving IC 172 may be mounted by a method of a chip on glass (COG), a tape carrier package (TOP), etc.

A control unit, such as an IC chip, a circuit unit, etc., may be mounted on the printed circuit board 180. In addition, a memory, a processor, etc., may also be mounted on the printed circuit board 180. For example, the printed circuit board 180 may be a component for transmitting signals for driving a display element from the control unit to the display element.

The printed circuit board 180 may be connected to the connection film 170 and electrically connected to each of the plurality of sub-pixels of the support substrate 111.

For example, the third cover layer CW3 is a substrate overlapping the fourth cover layer CW4 to protect various components of the display apparatus 1 and may be a second substrate (or an upper substrate). Specifically, the third cover layer CW3 may protect the display panel 10 disposed thereunder. The third cover layer CW3 is a flexible substrate and may be formed of a bendable or stretchable insulation material. The third cover layer CW3 is a flexible substrate and may reversibly expand and/or shrink.

For example, the third cover layer CW3 may be formed of a flexible material and formed of the same material as the fourth cover layer CW4, but is not limited thereto. For example, the third cover layer CW3 may be formed of silicon rubber of polydimethylsiloxane (PDMS), polyurethane, or polytetrafluoroethylene. However, the material of the third cover layer CW3 is not limited thereto.

A modulus of the third cover layer CW3 may range from 0.1 MPa to 1.5 MPa, preferably, may range from 0.5 MPa to 1.0 MPa. The modulus of the third cover layer CW3 may be the same as the modulus of the fourth cover layer CW4. However, the embodiments of the present disclosure are not limited thereto.

When the modulus of the third cover layer CW3 is smaller than the above range, a problem in a process that the third cover layer CW3 may not be smoothly fixed or a problem that the display panel 10 may not be smoothly supported and protected may occur.

When the modulus of the third cover layer CW3 is greater than the above range, problems that the resistance of a circuit of the display panel 10 increases, the circuit is short-circuited, etc., may occur.

Specifically, due to the stretching and recovery of the stretchable display apparatus 1, lines formed of a metal, such as the connection line 150, may be deformed in the thickness direction. In this case, when the modulus of the third cover layer CW3 is greater than the above range, a large stress may be applied to the deformed lines formed of a metal, such as the connection line 150, and thus the lines formed of a metal, such as the connection line 150, may have increased resistance or may be short-circuited.

Accordingly, when the modulus of the third cover layer CW3 falls within the above range, it is possible to protect and support the display panel 10 and suppress or prevent defects that may occur in the lines formed of a metal, such as the connection line 150, due to stretching and recovery of the stretchable display apparatus 1, thereby improving the reliability of the display panel 10.

A thickness of the third cover layer CW3 may range from 300 μm (micrometers) to 350 μm. The thickness of the third cover layer CW3 may be the same as the thickness of the fourth cover layer CW4. However, the embodiments of the present disclosure are not limited thereto.

When the thickness of the third cover layer CW3 is smaller than the above range, design and formation may be difficult in terms of process. When the thickness of the third cover layer CW3 is greater than the above range, the modulus of the third cover layer CW3 may increase, which may apply a large stress to the deformed lines formed of a metal, such as the connection line 150.

Accordingly, when the thickness of the third cover layer CW3 falls within the above range, the third cover layer CW2 can be smoothly designed and produced in terms of process, and it is possible to suppress or prevent defects that may occur in the lines formed of a metal, such as the connection line 150, due to stretching, recovery, etc., of the stretchable display apparatus 1, thereby improving the reliability of the display panel 10 and the display apparatus 1.

In addition, since the third cover layer CW3 and the fourth cover layer CW4 that are disposed above and below the display panel 10 have the same modulus and thickness, even when the stretching and recovery of the display apparatus 1 are repeated, stretching and recovery may occur above and below the display panel 10 in substantially the same manner. Accordingly, it is possible to minimize damage applied to the display panel 10. Furthermore, the display apparatus 1 can be bent or stretched more smoothly, and the life of the display apparatus 1 can be increased.

A transmittance of the third cover layer CW3 may be 90% or more, a haze of the third cover layer CW3 may be 1% or less, a yellow index (YI) may be 2 or less, and a stretch ratio may be 40% or more and 100% or less.

The display apparatus 1 of one embodiment of the present disclosure may include the active area divided into a plurality of first areas A1 in which the support substrate 111 is disposed and a plurality of second areas A2 in which a plurality of connection line 150 are disposed.

The plurality of first areas A1 are areas in which the support substrate 111 is disposed and may be rigid areas. For example, the plurality of first areas A1 may be spaced apart from each other and formed on the fourth cover layer CW4.

For example, a plurality of pixels, each of which includes a plurality of sub-pixels, may be formed on the support substrate 111 of the plurality of first areas A1. A plurality of light-emitting elements 140 and various transistors 120 for driving the plurality of light-emitting elements 140 may be disposed in each of the plurality of sub-pixels, and each of the plurality of sub-pixels may be connected to various lines. For example, a transistor 120 may be disposed on the support substrate 111, and the light-emitting element 140 may be disposed above the transistor 120 with a planarization layer 116 interposed therebetween.

The active area AA may include the plurality of second areas A2 adjacent to the plurality of first areas A1. For example, the plurality of second areas A2 may be disposed between two adjacent first areas A1.

The plurality of second areas A2 are areas in which the plurality of connection lines 150 and the plurality of connection substrates CS are disposed and may be flexible areas. The plurality of second areas A2 may be spaced apart from each other and disposed above the fourth cover layer CW4.

For example, the plurality of connection lines 150 and the plurality of connection substrates CS may be disposed in the plurality of second areas A2. For example, the connection lines 150 may be disposed above the connection substrate CS, and the connection line 150 may electrically connect the pad above the support substrate 111. The present disclosure is not limited thereto, and the connection substrate CS may be omitted or replaced with the support substrate 111.

The display panel 10 may be disposed between the third cover layer CW3 and the fourth cover layer CW4. The display panel 10 may include a plurality of display elements capable of emitting light. Through the display panel 10, the display apparatus 1 may display a screen.

Although not illustrated, a high-strength black matrix may be further disposed above the third cover layer CW3. When the black matrix is further disposed, it is possible to suppress or prevent a light leakage defect, etc.

The touch layer 20 may be disposed on the third cover layer CW3.

The touch layer 20 may sense the user's touch in a self-capacitance manner or a mutual capacitance manner. The touch layer 20 may include a plurality of touch electrodes. The plurality of touch electrodes may generate mutual capacitance or self-capacitance to sense the touch of an object or a person, but the embodiments of the present disclosure are not limited thereto.

In the present disclosure, the touch layer 20 is described as being provided separately from the third cover layer CW3, but the embodiments according to the present disclosure are not limited thereto. For example, the touch layer 20 may be formed integrally with the third cover layer CW3.

The second cover layer CW2 may be disposed on the touch layer 20. The second cover layer CW2 can protect various components thereunder. The second cover layer CW2 can protect the touch layer 20 thereunder.

The second cover layer CW2 is a flexible substrate and may be formed of a bendable or stretchable insulation material. For example, the second cover layer CW2 may be formed of an elastomer, such as silicon rubber of polydimethylsiloxane (PDMS), polyurethane (PU), polytetrafluoroethylene (PTFE), etc., and thus may be flexible. However, the material of the second cover layer CW2 is not limited thereto.

The modulus of the second cover layer CW2 may range from 3 MPa to 5 MPa.

When the modulus of the second cover layer CW2 is smaller than the above range, the second cover layer CW2 may be pressed by the stretching and recovery of the display apparatus 1, and thus, defects, such as the touch layer 20 being broken due to the pressing, an impact, etc., may occur.

When the modulus of the second cover layer CW2 is greater than the above range, problems that the resistance of a circuit of the display panel 10 increases, the circuit is short-circuited, etc., may occur.

Specifically, due to the stretching and recovery of the stretchable display apparatus 1, lines formed of a metal, such as the connection line 150, may be deformed in the thickness direction. In this case, when the modulus of the second cover layer CW2 is greater than the above range, a large stress may be applied to the deformed lines formed of a metal, such as the connection line 150, and thus the lines formed of a metal, such as the connection line 150, may have increased resistance or may be short-circuited.

Accordingly, when the modulus of the second cover layer CW2 falls within the above range, the second cover layer CW2 can have improved pressing characteristics and smoothly protect the touch layer 20, and it is possible to suppress or prevent defects that may occur in the lines formed of a metal, such as the connection line 150, due to stretching, recovery, etc., of the stretchable display apparatus 1, thereby improving the reliability of the display panel 10 and the display apparatus 1.

A thickness of the second cover layer CW2 may range from 300 μm (micrometers) to 400 μm. The thickness of the second cover layer CW2 may be the same as the thickness of the third cover layer CW3. However, the embodiments of the present disclosure are not limited thereto.

When the thickness of the second cover layer CW2 is smaller than the above range, the pressing characteristics of the second cover layer CW2 can be degraded, and thus, the second cover layer CW2 cannot smoothly protect the touch layer 20 thereunder. When the thickness of the second cover layer CW2 is greater than the above range, the overall thickness of the display apparatus 1 may increase, and design and production may be difficult in terms of process.

Accordingly, when the thickness of the second cover layer CW2 falls within the above range, the second cover layer CW2 can be smoothly designed and produced in terms of process and can smoothly protect the touch layer 20, and it is possible to suppress or prevent defects that may occur in the lines formed of a metal, such as the connection line 150, due to stretching, recovery, etc., of the stretchable display apparatus 1, thereby improving the reliability of the display panel 10.

A transmittance of the second cover layer CW2 may be 90% or more, a haze of the second cover layer CW2 may be 1% or less, a yellow index (YI) may be 2 or less, and a stretch ratio may be 20%.

The first cover layer CW1 may be disposed on the second cover layer CW2. The first cover layer CW1 can protect various components thereunder. The first cover layer CW1 may be disposed at an outermost edge of the display apparatus 1 and may protect other members below the first cover layer CW1.

By surface treatment, etc., for the first cover layer CW1, the first cover layer CW1 can have a tacky-less surface, and it is possible to suppress or prevent slip and scratches.

The first cover layer CW1 is a flexible substrate and may be formed of a bendable or stretchable insulation material. For example, the first cover layer CW1 may be formed of an elastomer, such as silicon rubber of polydimethylsiloxane (PDMS), polyurethane (PU), polytetrafluoroethylene (PTFE), etc., and thus may be flexible. However, the material of the first cover layer CW1 is not limited thereto.

The modulus of the first cover layer CW1 may range from 5 MPa to 7 MPa.

When the modulus of the first cover layer CW1 is smaller than the above range, it may be difficult to exhibit characteristics, such as tacky-less, slip-less, scratch-less, etc. In addition, it may be difficult to protect the remaining components disposed below the first cover layer CW1.

When the modulus of the first cover layer CW1 is greater than the above range, problems that the resistance of a circuit of the display panel 10 increases, the circuit is short-circuited, etc., may occur.

Specifically, due to the stretching and recovery of the stretchable display apparatus 1, lines formed of a metal, such as the connection line 150, may be deformed in the thickness direction. In this case, when the modulus of the first cover layer CW1 is greater than the above range, a large stress may be applied to the deformed lines formed of a metal, such as the connection line 150, and thus the lines formed of a metal, such as the connection line 150, may have increased resistance or may be short-circuited.

Accordingly, when the modulus of the first cover layer CW1 falls within the above range, the first cover layer CW1 can secure surface characteristics, and it is possible to suppress or prevent defects that may occur in the lines formed of a metal, such as the connection line 150, due to stretching, recovery, etc., of the stretchable display apparatus 1, thereby improving the reliability of the display panel 10 and the display apparatus 1.

A thickness of the first cover layer CW1 may range from 1 μm (micrometers) to 10 μm. The thickness of the first cover layer CW1 may be smaller than the thickness of the third cover layer CW3. However, the embodiments of the present disclosure are not limited thereto.

When the thickness of the first cover layer CW1 is smaller than the above range, the first cover layer CW1 may have degraded surface characteristics or cannot smoothly protect components thereunder. When the thickness of the first cover layer CW1 is greater than the above range, the overall thickness of the display apparatus 1 may increase, and problems that resistance of circuits of the display panel 10 increases, the circuits are short-circuited, etc., may occur.

Accordingly, when the thickness of the first cover layer CW1 falls within the above range, the first cover layer CW1 can be smoothly designed and produced in terms of process, and it is possible to suppress or prevent defects that may occur in the lines formed of a metal, such as the connection line 150, due to stretching, recovery, etc., of the stretchable display apparatus 1, thereby improving the reliability of the display panel 10.

A transmittance of the first cover layer CW1 may be 90% or more, a haze of the first cover layer CW1 may be 1% or less, a yellow index (YI) may be 2 or less, and a stretch ratio may be 20%.

Since the first cover layer CW1, the second cover layer CW2, and the third cover layer CW3 have different moduli and thicknesses and have higher moduli in a direction away from the display panel 10, the stretching and recovery of the display apparatus 1 can be smooth, and the function of each cover layer CW1, CW2, or CW3 can also be smoothly secured.

Specifically, since a cover layer having a relatively low modulus may be disposed, the stretching and recovery of the display apparatus 1 can be smoother. In addition, since a cover layer having a relatively high modulus may be disposed together, the components of the display apparatus 1 can be protected more smoothly, and surface characteristics can also be secured smoothly.

The back cover 30 may be disposed below the fourth cover layer CW4. The back cover 30 may support the remaining stacked members disposed thereabove.

The back cover 30 may be formed in a black-based color. In this case, it is possible to prevent light leakage of the light that is emitted from the display panel 10 and travels downward from the display apparatus 1. The back cover 30 may be substantially the same as the second cover layer CW2 and formed in a black-based color.

The back cover 30 is a flexible substrate and may be formed of a bendable or stretchable insulation material. For example, the back cover 30 may be formed of an elastomer, such as silicon rubber of polydimethylsiloxane (PDMS), polyurethane (PU), polytetrafluoroethylene (PTFE), etc., and thus may be flexible. However, the material of the back cover 30 is not limited thereto.

A modulus of the back cover 30 may be the same as the modulus of the cover layer of the second cover layer CW2, but the embodiments of the present disclosure are not limited thereto.

The modulus of the back cover 30 may range from 3 MPa to 5 MPa.

When the modulus of the back cover 30 is smaller than the above range, the back cover 30 cannot smoothly support the components thereabove.

When the modulus of the back cover 30 is greater than the above range, problems that the resistance of the circuit of the display panel 10 increases, the circuit is short-circuited, etc., may occur.

Specifically, due to the stretching and recovery of the stretchable display apparatus 1, lines formed of a metal, such as the connection line 150, may be deformed in the thickness direction. In this case, when the modulus of the back cover 30 is greater than the above range, a large stress may be applied to the deformed lines formed of a metal, such as the connection line 150, and thus the lines formed of a metal, such as the connection line 150, may have increased resistance or may be short-circuited.

Accordingly, when the modulus of the back cover 30 falls within the above range, the back cover 30 can be smoothly designed and produced in terms of process and can protect the touch layer 20, and it is possible to suppress or prevent defects that may occur in the lines formed of a metal, such as the connection line 150, due to stretching, recovery, etc., of the stretchable display apparatus 1, thereby improving the reliability of the display panel 10 and the display apparatus 1.

A thickness of the back cover 30 may be the same as the thickness of the second cover layer CW2, but the embodiments of the present disclosure are not limited thereto.

The thickness of the back cover 30 may range from 300 μm (micrometers) to 400 μm. The thickness of the back cover 30 may be greater than the thickness of the third cover layer CW3. However, the embodiments of the present disclosure are not limited thereto.

When the thickness of the back cover 30 is smaller than the above range, the pressing characteristics of the back cover 30 can be degraded, and thus, the back cover 30 cannot smoothly protect the touch layer 20 thereunder. When the thickness of the back cover 30 is greater than the above range, the overall thickness of the display apparatus 1 may increase, and design and production may be difficult in terms of process.

Accordingly, when the thickness of the back cover 30 falls within the above range, the back cover 30 can be smoothly designed and produced in terms of process and can smoothly protect the touch layer 20, and it is possible to suppress or prevent defects that may occur in the lines formed of a metal, such as the connection line 150, due to stretching, recovery, etc., of the stretchable display apparatus 1, thereby improving the reliability of the display panel 10.

In addition, since the second cover layer CW2 and the back cover 30 that are disposed above and below the display panel 10 have the same modulus and thickness, even when the stretching and recovery of the display apparatus 1 are repeated, stretching and recovery may occur above and below the display panel 10 in substantially the same manner. Accordingly, it is possible to minimize damage applied to the display panel 10. Furthermore, the display apparatus 1 can be bent or stretched more smoothly, the life of the display apparatus 1 can be increased, and power consumption can be reduced.

The adhesive layer 40 may include first to fourth adhesive layers 41, 42, 43, and 44. The adhesive layer 40 may be disposed between the stacked members to fixedly adhere the stacked members.

Each of the first to fourth adhesive layers 41, 42, 43, and 44 may be transparent and may include a material with high adhesion. For example, each of the first to fourth adhesive layers 41, 42, 43, and 44 may be a transparent material, such as an optical clear adhesive (OCA), an optically cleared resin (OCR), or a pressure sensitive adhesive (PSA), but is not limited thereto.

The first adhesive layer 41 may be disposed between the first cover layer CW1 and the second cover layer CW2 to adhere the first cover layer CW1 and the second cover layer CW2.

A second adhesive layer 42 may be disposed between the second cover layer CW2 and the touch layer 20 to adhere the second cover layer CW2 and the touch layer 20.

A third adhesive layer 43 may be disposed between the touch layer 20 and the third cover layer CW3 to adhere the touch layer 20 and the third cover layer CW3.

The fourth adhesive layer 44 may be disposed between the fourth cover layer CW4 and the back cover 30 to adhere the fourth cover layer CW4 and the back cover 30.

Hereinafter, the display panel 10 will be described in detail.

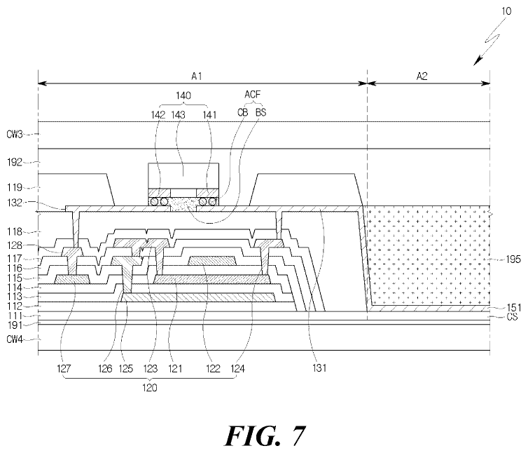

FIG. 6 is an enlarged plan view illustrating the display apparatus according to one embodiment. FIG. 7 is a cross-sectional view of one pixel of the display apparatus according to one embodiment. FIGS. 6 and 7 illustrate an enlarged plan view and a cross-sectional view of the display panel 10, respectively.

Referring to FIGS. 6 and 7, the display panel 10 may be disposed between the fourth cover layer CW4 and the third cover layer CW3.

The display panel 10 may include the support substrate 111, the connection substrate CS, a buffer layer 112, the transistor 120, a light-blocking layer 125, a first insulating layer 113, a second insulating layer 114, a third insulating layer 115, a first connection electrode 126, a fourth insulating layer 116, a second connection electrode 128, a fifth insulating layer 117, a sixth insulating layer 118, a first pad 131, a second pad 132, a light-emitting clement 140, a bank 119, the connection line 150, a first adhesive member 191, a second adhesive member 192, and a fifth adhesive member 195.

The fourth cover layer CW4 may include the plurality of first areas A1 in which the support substrate 111 is disposed and the plurality of second areas A2 in which the plurality of connection lines 150 are disposed.

For example, the plurality of first areas A1 of the fourth cover layer CW4 are areas in which the support substrate 111 is disposed and may be rigid areas. The plurality of first areas A1 may be spaced apart from each other and disposed above the fourth cover layer CW4. For example, the plurality of first areas A1 may be disposed in a matrix form above the fourth cover layer CW4 as illustrated in FIGS. 3 and 6, but are not limited thereto.

The plurality of pixels PX, each of which includes a plurality of sub-pixels SPX, may be included on the support substrates 111 of the plurality of first areas A1. A plurality of light-emitting elements 140 and various driving elements for driving the plurality of light-emitting elements 140 may be disposed in each of the plurality of sub-pixels SPX, and each of the plurality of sub-pixels SPX may be connected to various lines. For example, each of the plurality of sub-pixels SPX may be connected to various lines, such as a gate line, a data line, a high-potential voltage line, a low-potential voltage line, a reference voltage line, a common line 127, etc.

For example, the fourth cover layer CW4 may include the plurality of second areas A2 adjacent to the plurality of first areas A1. The plurality of second areas A2 may be disposed between two adjacent first areas A1. Accordingly, as illustrated in FIG. 6, the plurality of second areas A2 may exist at upper, lower, left, and right sides of one first area A1.

For example, the plurality of second areas A2 are areas in which the plurality of connection lines 150 and the plurality of connection substrates CS are disposed and may be flexible areas. The plurality of second areas A2 may be spaced apart from each other and disposed above the fourth cover layer CW4. For example, the plurality of second areas A2 may be disposed in a matrix form above the fourth cover layer CW4 as illustrated in FIGS. 3 and 6, but are not limited thereto.

For example, the plurality of connection lines 150 and the plurality of connection substrates CS may be disposed in the plurality of second areas A2 of the fourth cover layer CW4. The plurality of connection lines 150 may be disposed on the plurality of connection substrates CS.

In the case of conventional display apparatuses, various lines, such as a plurality of gate lines, a plurality of data lines, etc., may be disposed to extend between the plurality of sub-pixels, and the plurality of sub-pixels may be connected to one signal line. Accordingly, in the case of the conventional display apparatuses, various lines, such as a gate line, a data line, a high-potential voltage line, and a reference voltage line, may seamlessly extend from one side to the other side of the display apparatus on the substrate.

In the case of the display apparatus 1 according to one embodiment of the present disclosure, various lines, such as a gate line, a data line, a high-potential voltage line, a low-potential voltage line, a reference voltage line, and the common line 127 that are formed of a metallic material may be disposed only on the support substrate 111. In the display apparatus 1 according to one embodiment of the present disclosure, various lines formed of a metallic material may be disposed only on the support substrate 111 and disposed so as not to be in contact with the fourth cover layer CW4. Accordingly, various lines formed of a metallic material may be patterned to correspond to the support substrate 111 and discontinuously disposed.

In the display apparatus 1 according to one embodiment of the present disclosure, the plurality of connection lines 150 may be disposed between two adjacent support substrates 111 to connect the discontinuous lines on the support substrates 111. For example, the plurality of connection lines 150 may be connected to pads on two adjacent support substrates 111, respectively. In addition, various lines, such as a gate line, a data line, a high-potential voltage line, a low-potential voltage line, a reference voltage line, and the common line 127 on two adjacent support substrates 111, may be electrically connected by the plurality of connection line 150.

For example, the gate line may be disposed on the support substrates 111 disposed adjacent to each other in the X-axis direction, and gate pads may be disposed on both ends (or one side) of the gate line. Each of the plurality of gate pads on the support substrates 111 disposed adjacent to each other in the X-axis direction may be connected by the plurality of connection lines 150 that serve as the gate lines. Accordingly, the gate lines disposed on the support substrate 111 of the first area A1 and the plurality of connection lines 150 disposed in the second area A2 may serve as a single gate line.

In addition, all of various lines that may be included in the display apparatus 100, such as a data line, a high-potential voltage line, a low-potential voltage line, a reference voltage line, and the common line 127, may serve as a single line by the plurality of connection lines 150. The plurality of connection lines 150 may be disposed on the plurality of connection substrates CS. The plurality of connection substrates CS may have a curved shape. Accordingly, the plurality of connection lines 150 disposed on the plurality of connection substrates CS may also have a curved shape like the plurality of connection substrates CS.

For example, the plurality of connection lines 150 may be formed of a conductive material. The plurality of connection lines 150 may be formed of the same material as various conductive components disposed on the support substrate 111, for example, may be formed of a metallic material, but are not limited thereto, and may include a base polymer and conductive particles dispersed in the base polymer.

The plurality of connection lines 150 may include a plurality of first connection lines 151 and a plurality of second connection lines 152.

The plurality of first connection lines 151 may be lines extending in the X-axis direction among the plurality of connection lines 150. The plurality of first connection lines 151 may connect the pads on two adjacent support substrates 111 among the support substrates 111 disposed adjacent to each other in the X-axis direction. The plurality of first connection lines 151 may serve as gate lines, low-potential voltage lines, etc., but are not limited thereto. For example, when the plurality of first connection lines 151 serve as the gate lines, gate pads on two support substrates 111 disposed side by side in the X-axis direction may be electrically connected.

The plurality of second connection lines 152 may be lines extending in the Y-axis direction among the plurality of connection lines 150. The plurality of second connection lines 152 may connect the pads on two adjacent support substrates 111 among the support substrates 111 disposed adjacent to each other in the Y-axis direction. The plurality of second connection lines 152 may serve as data lines, high-potential voltage lines, etc., but are not limited thereto. For example, when the plurality of second connection lines 152 serve as the data lines, data pads on two support substrates 111 disposed side by side in the Y-axis direction may be electrically connected.

The first adhesive member 191 may be disposed between the fourth cover layer CW4 and the support substrate 111, but may be omitted according to the configuration of the display apparatus 1.

The first adhesive member 191 may include an adhesive. For example, the first adhesive member 191 may include an OCA, but is not limited thereto.

The first adhesive member 191 may be disposed on the fourth cover layer CW4 including the first area A1 and the second area A2 in a tape manner. For example, the first adhesive member 191 may be disposed entirely on the fourth cover layer CW4 including the first area A1 and the second area A2. For example, the first adhesive member 191 may include an adhesive having the same lap shear modulus as the second adhesive member 192.

In addition, since the fifth adhesive member 195 may be configured by an inkjet method to be selectively formed on the connection line 150, there is an advantage that a process is easy. In addition, the fifth adhesive member 195 formed on the connection line 150 may be formed without affecting the light-emitting element 140.

The buffer layer 112 may be disposed on the support substrate 111.

The buffer layer 112 may be disposed on the support substrate 111 to protect various components of the display apparatus 1 from the penetration of external moisture, oxygen, etc., of the fourth cover layer CW4 and the support substrate 111. The buffer layer 112 may be formed of an insulation material and may be formed of a single layer or multiple layers of an inorganic layer formed of, for example, silicon nitride (SiNₓ), silicon oxide (SiOₓ), silicon oxide nitride (SiON), etc. The buffer layer 112 may be omitted according to the structure or characteristics of the display apparatus 1.

The buffer layer 112 may be disposed only in an area overlapping the support substrate 111. As described above, since the buffer layer 112 may be formed of an inorganic layer, the buffer layer 112 can be easily damaged, such as cracks, during the process of stretching the display apparatus 1.

Accordingly, the buffer layer 112 is not disposed in the second area A2 between the support substrates 111, may be patterned in the shape of the support substrate 111, and disposed only on the support substrate 111. In this way, the display apparatus 1 according to one embodiment of the present disclosure can prevent damage to the buffer layer 112 even when the display apparatus 1 is deformed, such as bending, stretching, etc., by arranging the buffer layer 112 only in the area overlapping the support substrate 111, which is a rigid substrate.

The transistor 120 including a gate electrode 122, an active layer 121, a source electrode 123, and a drain electrode 124 may be disposed on the buffer layer 112.

First, the light-blocking layer 125 may be disposed on the buffer layer 112. The light-blocking layer 125 may be disposed below the transistor 120 to cover the active layer 121.

The light-blocking layer 125 may be formed of an opaque metallic material, for example, at least one of conductive metals including aluminum (Al), tungsten (W), copper (Cu), molybdenum (Mo), chromium (Cr), titanium (Ti), molytungsten (MoW), molytitanium (MoTi), and copper/molytitanium (Cu/MoTi). However, the embodiments of the present disclosure are not limited thereto, and any metallic material capable of blocking light is possible.

The first insulating layer 113 may be disposed on the light-blocking layer 125. The first insulating layer 113 may be referred to as another buffer layer. For example, the first insulating layer 113 may be formed of silicon oxide (SiOₓ), silicon nitride (SiNₓ), or a multilayer thereof, but is not limited thereto.

The active layer 121 may be disposed on the first insulating layer 113. For example, the active layer 121 may be formed of an oxide semiconductor and formed of amorphous silicon (a-Si), polycrystalline silicon (poly-Si), or an organic semiconductor, but is not limited thereto.

The second insulating layer 114 may be disposed on the active layer 121. For example, the second insulating layer 114 may be a layer for electrically insulating the gate electrode 122 and the active layer 121 and may be a gate insulating layer.

For example, the second insulating layer 114 may be formed of silicon oxide (SiOₓ), silicon nitride (SiNₓ), or a multilayer thereof, but is not limited thereto.

The gate electrode 122 may be disposed on the second insulating layer 114.

The gate electrode 122 may be disposed to overlap the active layer 121. The gate electrode 122 may be formed of one of various metal materials, for example, molybdenum (Mo), aluminum (Al), chromium (Cr), gold (Au), titanium (Ti), nickel (Ni), neodymium (Nd), and copper (Cu), an alloy of two or more thereof, or a multilayer thereof, but is not limited thereto.

The common line 127 may be disposed on the same layer as the active layer 121. The common line 127 may be a line through which a common voltage is applied to the plurality of sub-pixels SPX. However, the embodiments of the present disclosure are not limited thereto, and the common line 127 may be disposed on the same layer as the source electrode 123 and the drain electrode 124.

The gate pad may be disposed on the same layer as the gate electrode 122. The gate pad may be a pad for transmitting a gate signal to the plurality of sub-pixels SPX. The gate pad may be formed of the same material as the gate electrode 122, but is not limited thereto.

The gate pad may transmit the gate signal from the connection line 150 that serves as the gate line to the plurality of sub-pixels SPX. For example, the gate pad may be connected to the connection line 150 and may transmit the gate signal to the plurality of sub-pixels SPX.

The third insulating layer 115 may be disposed on the gate electrode 122.

For example, the third insulating layer 115 may be a layer for insulating between the gate electrode 122 and the source and drain electrodes 123 and 124 and may be a first interlayer insulating layer. For example, the third insulating layer 115 may be formed of silicon oxide (SiOₓ), silicon nitride (SiNₓ), or a multilayer thereof, but is not limited thereto.

The first connection electrode 126 may be disposed on the third insulating layer 115 and may be omitted according to the configuration of the display apparatus 1. The first connection electrode 126 may be electrically connected to the light-blocking layer 125 thereunder through a contact hole.

The fourth insulating layer 116 may be disposed on the first connection electrode 126.

For example, the fourth insulating layer 116 may be a layer for insulating between the gate electrode 122 and the source and drain electrodes 123 and 124 and may be a second interlayer insulating layer. For example, the fourth insulating layer 116 may be formed of silicon oxide (SiOₓ), silicon nitride (SiNₓ), or a multilayer thereof, but the embodiments of the present disclosure are not limited thereto.

However, the embodiments of the present disclosure are not limited thereto, and the fourth insulating layer 116 may be a planarization layer. In this case, the fourth insulating layer 116 may include an organic insulation material. For example, the fourth insulating layer 116 may be formed of an acryl-based organic material, but is not limited thereto.

The source electrode 123 and the drain electrode 124 respectively connected to a source area and a drain area of the active layer 121 may be disposed on the fourth insulating layer 116. The source electrode 123 and the drain electrode 124 may be disposed to be spaced apart from each other on the same layer. The source electrode 123 and the drain electrode 124 may be formed of one of various metal materials, for example, molybdenum (Mo), aluminum (Al), chromium (Cr), gold (Au), titanium (Ti), nickel (Ni), neodymium (Nd), and copper (Cu), an alloy of two or more thereof, or a multilayer thereof, but are not limited thereto.

For example, the source electrode 123 may be electrically connected to the light-blocking layer 125 through the first connection electrode 126. FIG. 7 illustrates the light-blocking layer 125 electrically connected to the source electrode 123 of the transistor 120, but the embodiments of the present disclosure are not limited thereto, and the light-blocking layer 125 may be electrically connected to the drain electrode 124.

The first insulating layer 113, the second insulating layer 114, the third insulating layer 115, and the fourth insulating layer 116 may be patterned and disposed only in the areas overlapping the support substrate 111. For example, the first insulating layer 113, the second insulating layer 114, the third insulating layer 115, and the fourth insulating layer 116 may be formed of an inorganic material like the buffer layer 112. Accordingly, cracks can easily occur on the first insulating layer 113, the second insulating layer 114, the third insulating layer 115, and the fourth insulating layer 116 during the process of extending the display apparatus 1 as described above. Accordingly, the first insulating layer 113, the second insulating layer 114, the third insulating layer 115, and the fourth insulating layer 116 are not disposed in the area between the support substrates 111 and may be patterned in the shape of the support substrate 111 and disposed only on the support substrate 111.

For convenience of description, FIG. 7 illustrates only the driving transistor 120 among various transistors that may be included in the display apparatus 1, but a switching transistor, a capacitor, etc., may also be included in the display apparatus 1. In addition, FIG. 7 illustrates the transistor 120 having a coplanar structure, but various transistors, such as a staggered structure, may also be used.

The second connection electrode 128 may be disposed on the fourth insulating layer 116 and may be omitted according to the configuration of the display apparatus 1.

The second connection electrode 128 may be electrically connected to the common line 127 thereunder through a contact hole.

The fifth insulating layer 117 may be disposed on the source electrode 123, the drain electrode 124, and the second connection electrode 128. For example, the fifth insulating layer 117 may be a protective layer. The fifth insulating layer 117 may be disposed to cover the transistor 120 to protect the transistor 120 from penetration of moisture, oxygen, etc. In this case, the fifth insulating layer 117 may be formed of an inorganic material and formed of a single layer or multiple layers, but is not limited thereto.

However, the embodiments of the present disclosure are not limited thereto, and the fifth insulating layer 117 may be omitted or may include an organic material. When the fifth insulating layer 117 includes an organic material, the fifth insulating layer 117 may be a planarization layer and may be formed of an acryl-based organic material, but is not limited thereto.

The sixth insulating layer 118 may be disposed on the fifth insulating layer 117. For example, the sixth insulating layer 118 may be a planarization layer.

The sixth insulating layer 118 may planarize an upper portion of the support substrate 111 including the transistor 120 or planarize a upper portion of the sixth insulating layer 118 on which the light-emitting element 140 is disposed. For example, the sixth insulating layer 118 may be formed of an organic material. For example, the sixth insulating layer 118 may be formed of an acryl-based organic material, but is not limited thereto.

The fifth insulating layer 117 and the sixth insulating layer 118 may include a contact hole for electrically connecting the transistor 120 to the light-emitting element 140, a contact hole for electrically connecting the pad to the connection pad, and a contact hole for electrically connecting the common line 127 to the light-emitting element 140.

For example, the fifth insulating layer 117 and the sixth insulating layer 118 may be patterned and disposed only in the area overlapping the support substrate 111. The fifth insulating layer 117 and the sixth insulating layer 118 are not disposed in the area between the support substrates 111 and may be patterned in the shape of the support substrate 111 and disposed only on the support substrate 111, but are not limited thereto.

The first pad 131 and the second pad 132 may be disposed on the sixth insulating layer 118. For example, the first pad 131 may be an electrode that electrically connects the transistor 120 to the light-emitting element 140. For example, the first pad 131 may be disposed on the sixth insulating layer 118 and may be in contact with the light-emitting element 140, and the first pad 131 may be in contact with the drain electrode 124 of the transistor 120 through a contact hole formed in the sixth insulating layer 118.

Accordingly, the light-emitting element 140 and the transistor 120 may be electrically connected by the first pad 131. According to the type of the transistor 120, the first pad 131 may be connected to the source electrode 123 of the transistor 120, but is not limited thereto.

The second pad 132 is an electrode that electrically connects the light-emitting element 140 to the common line 127. The second pad 132 may be disposed on the sixth insulating layer 118 and may be in contact with the light-emitting element 140, and the second pad 132 may be in contact with the second connection electrode 128 through the contact hole formed in the sixth insulating layer 118. Accordingly, the light-emitting clement 140 and the common line 127 may be electrically connected by the second pad 132 and the second connection electrode 128.

In the plurality of second areas A2, the connection line 150 may be disposed on the connection substrate CS. For example, the connection line 150 may be connected to the first pad 131. In addition, the connection line 150 may be connected to the data pad through the contact hole.

Accordingly, the connection line 150 may be electrically connected to the data pad and may transmit a data signal to the data pad. In addition, the connection line 150 may be connected to the gate pad through the contact hole. Accordingly, the connection line 150 may be electrically connected to the gate pad and may transmit a gate signal to the gate pad.

The fifth adhesive member 195 including elastic hollow particles may be disposed on the connection line 150.

For example, the fifth adhesive member 195 may be coated or formed on the connection line 150 using an inkjet method. The inkjet method enables selective coating in the second area A2 and enables large-area printing, thereby optimizing the process.

The fifth adhesive member 195 may include an adhesive having a relatively low lap shear modulus. For example, the fifth adhesive member 195 may include an adhesive resin. For example, the fifth adhesive member 195 may include an OCR. For example, the fifth adhesive member 195 may include an adhesive having a lower lap shear modulus than the second adhesive member 192.

In addition, the fifth adhesive member 195 may be selectively coated (or formed) on a desired area, for example, the second area A2 in which deformation is concentrated, using an inkjet method and may restore deformation, such as compression of the second area A2 deformed during stretching, without affecting the first area A1 having rigidity.

FIG. 7 illustrates an example in which the fifth adhesive member 195 according to the embodiment of the present disclosure is coated (or formed) to have substantially the same height (level) as the first pad 131 and the second pad 132 of the first area A1, but the embodiments of the present disclosure are not limited thereto, and the fifth adhesive member 195 of the present disclosure may be coated (or formed) to have a lower height than the first pad 131 and the second pad 132.

The bank 119 may be disposed on the first pad 131, the second pad 132, and the sixth insulating layer 118. For example, the bank 119 may be formed to include a black material to prevent the light emitted from the light emitting element 140 from being transmitted to an adjacent sub-pixel SPX and being color-mixed. The bank 119 may be formed of an organic insulation material and formed of the same material as the sixth insulating layer 118. For example, the bank 119 may be formed of an acrylic resin, a benzocyclobutene (BCB)-based resin, or a polyimide, but is not limited thereto.

For example, the light-emitting element 140 may be disposed on the first pad 131, the second pad 132, and the sixth insulating layer 118. The light-emitting element 140 may be a component that is disposed to correspond to each of the plurality of sub-pixels SPX and emits light in a specific wavelength range. For example, the light-emitting element 140 may be a blue light-emitting element that emits blue light, a red light-emitting element that emits red light, or a green light-emitting element that emits green light, but is not limited thereto.

However, the embodiments of the present disclosure are not limited thereto, and the bank 119 may be omitted.

The light-emitting element 140 may be configured differently according to the type of the display apparatus 1. When the display apparatus 1 is an organic light-emitting diode display apparatus, the light-emitting element 140 may be an organic light-emitting element including an anode, an organic light-emitting layer, and a cathode. When the display apparatus 1 is an inorganic light-emitting diode display apparatus, the light-emitting element 140 may be a light-emitting diode (LED), particularly, a micro LED, including an n-type semiconductor layer, a light-emitting layer, and a p-type semiconductor layer.

In the following description, it is assumed that the light-emitting element 140 is a micro LED formed of an inorganic light-emitting material, but the embodiments of the present disclosure are not limited thereto, and the light-emitting element 140 may be formed as a light-emitting element formed of an organic light-emitting material. When the light-emitting element 140 is formed as a micro LED, there is an advantage that it is possible to prevent a change in image quality even in the event of an external impact.

The light-emitting element 140 may include a first electrode 141, a second electrode 142, and a light-emitting part 143.

In the following description, for convenience of description, it is assumed that the light-emitting element 140 is a micro LED having a flip-chip structure, but the light-emitting element 140 may be a micro LED having a lateral structure or a vertical structure, and is not limited thereto.

The first electrode 141 may be disposed on the first pad 131, and the second electrode 142 may be disposed on the second pad 132. The first electrode 141 and the second electrode 142 may be electrically connected to the first pad 131 and the second pad 132, respectively. For example, the first electrode 141 may transmit a voltage from the drain electrode 124 of the transistor 120 to the light-emitting part 143, and the second electrode 142 may transmit a voltage from the common line 127 to the light-emitting part 143.

A conductive adhesive member ACF may be disposed between the first electrode 141 and the first pad 131 and between the second electrode 142 and the second pad 132. The conductive adhesive member ACF may bond and electrically connect the first electrode 141 to the first pad 131. The conductive adhesive member ACF may bond and electrically connect the second electrode 142 to the second pad 132.

The conductive adhesive member ACF may include a binder layer BS and a conductive ball CB.

The binder layer BS may be formed of at least one selected from a thermosetting resin and a thermoplastic resin. For example, the thermosetting resin may include a bisphenol A type epoxy resin, a bisphenol F type epoxy resin, a novolak type epoxy resin, a phenol resin, a urea resin, a melamine resin, an unsaturated polyester resin, a resorcinol resin, etc., and the thermoplastic resin may include a saturated polyester resin, a vinyl resin, an acrylic resin, a polyolefin resin, a polyvinyl acetate (PVA) resin, a polycarbonate resin, a cellulose resin, a ketone resin, a styrene resin, etc., but is not limited thereto.

The conductive ball CB may be provided as a plurality of conductive balls inside the binder layer BS. The conductive ball CB may be an electrically conductive fine particle. The conductive ball CB may include at least one metal selected from nickel (Ni), iron (Fe), copper (Cu), aluminum (Al), tin (Sn), zinc (Zn), chromium (Cr), cobalt (Co), silver (Ag), and gold (Au).

Each of the plurality of conductive balls CB may be a spherical metal particle including a metal. Each of the plurality of conductive balls CB may have a core-shell structure including a core and a shell surrounding the core. A particle size of the conductive ball CB may range from 1 μm to 10 μm or range from 2 μm to 5 μm.

The plurality of conductive balls CB may electrically connect the first electrode 141 to the first pad 131 and electrically connect the second electrode 142 to the second pad 132 between the first electrode 141 and the first pad 131 and between the second electrode 142 and the second pad 132.

However, a method of electrically connecting each electrode 141 or 142 to each pad 131 or 132 is not limited thereto. For example, an anisotropic conductive paste (ACP) may be disposed between the first electrode 141 and the first pad 131 and between the second electrode 142 and the second pad 132.

The light-emitting part 143 may be disposed on the first electrode 141 and the second electrode 142. The light-emitting part 143 may emit light. The first electrode 141 and the second electrode 142 may be disposed on the same side of the light-emitting part 143, but are not limited thereto.

The light-emitting part 143 may include, for example, a first semiconductor layer, a light-emitting layer, and a second semiconductor layer. The light-emitting layer may be disposed between the first semiconductor layer and the second semiconductor layer. The first semiconductor layer may be electrically connected to the first electrode 141, and the second semiconductor layer may be electrically connected to the second electrode 142.

When the display apparatus 1 is turned on, a plurality of light-emitting elements 140 on the support substrate 111 may be turned on. For example, a voltage of a different level may be applied to each of the drain electrode 124 of the transistor 120 and the common line 127 electrically connected to the plurality of light-emitting elements 140. In addition, a voltage may be applied from the drain electrode 124 of the transistor 120 to the first electrode 141 of the light-emitting element 140, and a common voltage may be applied from the common line 127 to the second electrode 142. Since voltages of different levels are applied to the first electrode 141 and the second electrode 142 of the light-emitting element 140, a current flows to the light-emitting part 143 so that the light-emitting element 140 may emit light.

The second adhesive member 192 may be disposed entirely above the support substrate 111 on which the light-emitting clement 140 is disposed, the connection line 150, and the connection substrate CS on which the fifth adhesive member 195 is disposed. For example, the second adhesive member 192 may include an adhesive having a relatively high lap shear modulus. For example, the second adhesive member 192 may include an OCA. For example, the second adhesive member 192 may be attached or disposed on the substrate 110 of the entireties of the first area A1 and the second area A2 in a tape manner. For example, the second adhesive member 192 may be commonly disposed on the light-emitting element 140 of the first area A1 and the fifth adhesive member 195 of the second area A2, but is not limited thereto.

The third cover layer CW3 may be disposed on the second adhesive member 192. The third cover layer CW3 may cover the plurality of light-emitting elements 140, the transistor 120, etc.

Hereinafter, other embodiments of the present disclosure will be described. For contents that are substantially the same as those described with reference to FIGS. 1 to 7 among components included in other embodiments, the same reference numerals are given, and overlapping contents may be omitted or briefly described.

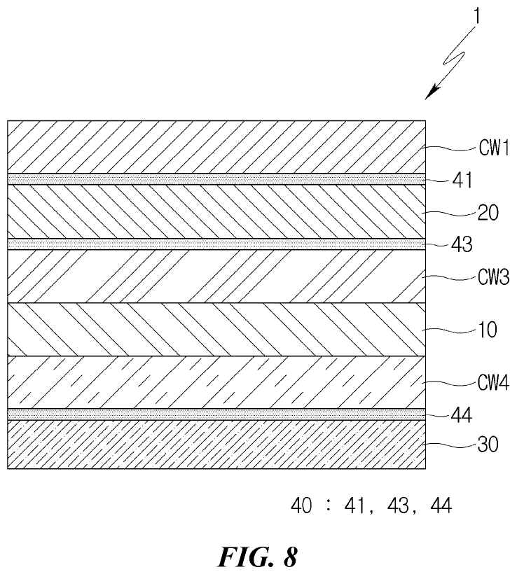

FIG. 8 is a cross-sectional view of a display apparatus according to another embodiment.

Referring to FIG. 8, a display apparatus 1_1 according to the present embodiment may include the first cover layer CW1 disposed on the touch layer 20. The touch layer 20 and the first cover layer CW1 may be coupled by the first adhesive layer 41. That is, in one embodiment, the second cover layer CW2 (see FIG. 4) disposed between the touch layer 20 and the first cover layer CW1 may be omitted.

The modulus of the first cover layer CW1 may range from 5 MPa to 7 MPa. The modulus of the first cover layer CW1 may be greater than the modulus of the third cover layer CW3. However, the embodiments of the present disclosure are not limited thereto.

The thickness of the first cover layer CW1 may range from 1 μm (micrometers) to 10 μm. The thickness of the first cover layer CW1 may be smaller than the thickness of the third cover layer CW3. However, the embodiments of the present disclosure are not limited thereto.

The transmittance of the first cover layer CW1 may be 90% or more, a haze of the first cover layer CW1 may be 1% or less, a yellow index (YI) may be 2 or less, and a stretch ratio may be 20%.

Even in this case, since the display apparatus 1_1 includes the cover layers CW1, CW3, and CW4 and the back cover 30 that have different moduli, it is possible to secure a sufficient stretch ratio and stretch the display apparatus without damage to circuit elements of the display panel. Furthermore, it is possible to increase the life of the display apparatus 1_1, thereby reducing power consumption.

In addition, since the number of cover layers disposed in the display apparatus 1_1 decreases, the process can be further simplified, and process cost, required time, etc., can be reduced.

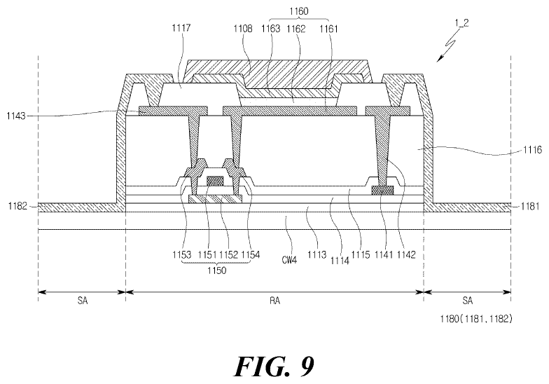

FIG. 9 is a cross-sectional view of a display apparatus according to still another embodiment. FIG. 9 illustrates a cross-sectional structure of one pixel of a display apparatus 1_2.

Referring to FIG. 9, the display apparatus 1_2 may include a rigid area RA and a soft area SA. An area in which a thin film transistor 1150 and a light-emitting element 1160 are disposed may be referred to as the rigid area RA, and an area in which a first connection line 1181 and a second connection line 1182 are disposed may be referred to as the soft area SA.

The rigid area RA of FIG. 9 may be substantially the same as the first area A1 of FIG. 7, and the soft area SA of FIG. 9 may be substantially the same as the second area A2 of FIG. 7. In the present embodiment, for convenience of description, the first area A1 and the second area A2 will be described as the rigid area RA and the soft area SA, respectively.

In the rigid area RA and the soft area SA, the fourth cover layer CW4 may be disposed. A buffer layer 1113 may be disposed on the fourth cover layer CW4 of the rigid area RA. The buffer layer 1113 may be formed of an insulation material and may be formed of a single layer or multiple layers of an inorganic layer formed of, for example, silicon nitride (SiNₓ), silicon oxide (SiOₓ), silicon oxide nitride (SiON), etc. However, the embodiments of the present disclosure are not limited thereto.

The buffer layer 1113 may be disposed in an area overlapping the fourth cover layer CW4 of the rigid area RA to protect various components of the stretchable display apparatus 1_2 from penetration of external moisture, oxygen, etc. Since the buffer layer 1113 may be formed of an inorganic material, the buffer layer 1113 can be easily damaged, such as cracks, during the process of stretching the stretchable display apparatus 1_2. Accordingly, the buffer layer 1113 is not formed in the soft area SA, which is a spacing area between the plurality of fourth cover layers CW4, and may be patterned similarly to the shape of the fourth cover layer CW4 of the rigid area RA and formed on the fourth cover layer CW4 of the rigid area RA. Accordingly, in the stretchable display apparatus 1_2 according to one embodiment of the present disclosure, since the buffer layer 1113 is formed in the area overlapping the fourth cover layer CW4 of the rigid area RA, it is possible to prevent damage to the buffer layer even when the stretchable display apparatus 1_2 is deformed, such as bending, stretching, etc. As another example, the buffer layer 1113 may be omitted according to the structure or characteristics of the stretchable display apparatus 1_2.

The transistor 1150 including a gate electrode 1151, an active layer 1152, a source electrode 1153, and a drain electrode 1154 may be disposed on the buffer layer 1113. For example, describing a process of forming the transistor 1150, the active layer 1152 may be disposed on the buffer layer 1113, and a gate insulating layer 1114 may be disposed on the active layer 1152 to insulate the active layer 1152 and the gate electrode 1151. An interlayer insulating layer 1115 may be disposed to insulate the gate electrode 1151, the source electrode 1153, and the drain electrode 1154. The source electrode 1153 and the drain electrode 1154 that are each in contact with the active layer 1152 may be disposed on the interlayer insulating layer 1115.

In addition, the gate insulating layer 1114 and the interlayer insulating layer 1115 may be patterned and disposed in an area overlapping the fourth cover layer CW4 of the rigid area RA. Since the gate insulating layer 1114 and the interlayer insulating layer 1115 may also be formed of an inorganic material like the buffer layer 1113, damage, such as cracks, can easily occur during the process of stretching the stretchable display apparatus 1_2. Accordingly, the gate insulating layer 1114 and the interlayer insulating layer 1115 are not formed in an area between the fourth cover layers CW4 in which the thin film transistor 1150 is disposed, for example, in the soft area SA and may be patterned similarly to the shape of the fourth cover layer CW4 of the rigid area RA and disposed on the fourth cover layer CW4 of the rigid area RA.

For convenience of description, FIG. 9 illustrates only a driving thin film transistor among various thin film transistors that may be included in the stretchable display apparatus 1_2, but a switching thin film transistor, a capacitor, etc., may also be included in the display apparatus. In addition, in the present disclosure, the thin film transistor 1150 is described as having a coplanar structure, but is not limited thereto, and various transistors, such as a staggered structure, may be used.

A gate pad 1141 may be disposed on the gate insulating layer 1114. The gate pad 1141 may be a pad for transmitting a gate signal to a plurality of sub-pixels. The gate pad 1141 may be formed of the same material as the gate electrode 1151, but is not limited thereto.

A planarization layer 1116 may be disposed on the thin film transistor 1150 and the interlayer insulating layer 1115. The planarization layer 1116 may planarize an upper portion of the thin film transistor 1150. The planarization layer 1116 may be formed of a single layer or multiple layers and formed of an organic material, but is not limited thereto. For example, the planarization layer 1116 may be formed of an acryl-based organic material, but is not limited thereto. The planarization layer 1116 may include a contact hole for electrically connecting the thin film transistor 1150 to a first electrode 1161 of the light-emitting element 1160, a contact hole for electrically connecting a data pad 1143 to the source electrode 1153, and a contact hole for electrically connecting a connection pad 1142 and the gate pad 1141.

In some embodiments, a passivation layer may be disposed between the thin film transistor 1150 and the planarization layer 1116. For example, the passivation layer may be disposed to cover the thin film transistor 1150 or on the thin film transistor 1150 to protect the thin film transistor 1150 from penetration of moisture, oxygen, etc. The passivation layer may be formed of an inorganic material and formed of a single layer or multiple layers, but the embodiments of the present disclosure are not limited thereto.

The data pad 1143, the connection pad 1142, and the light-emitting element 1160 may be disposed on the planarization layer 1116.

The data pad 1143 may transmit a data signal from a second connection line 1182, which serves as a data line, to the plurality of sub-pixels. The data pad 1143 is connected to the source electrode 1153 of the thin film transistor 1150 through a contact hole formed in the planarization layer 1116. The data pad 1143 may be formed of the same material as the first electrode 1161 of the light-emitting clement 1160, but is not limited thereto. As another example, the data pad 1143 may be disposed on the interlayer insulating layer 1115 rather than on the planarization layer 1116 and formed of the same material as the source electrode 1153 and the drain electrode 1154 of the thin film transistor 1150, but is not limited thereto.

The connection pad 1142 may transmit a gate signal from the first connection line 1181, which serves as a gate line, to the plurality of sub-pixels. The connection pad 1142 may be connected to the gate pad 1141 through the contact hole formed in the planarization layer 1116 and the interlayer insulating layer 1115 and may transmit the gate signal to the gate pad 1141. The connection pad 1142 may be formed of the same material as the data pad 1143, but is not limited thereto.

The light-emitting element 1160 may include a first electrode 1161, a light-emitting layer 1162, and a second electrode 1163. For example, the first electrode 1161 may be disposed on the planarization layer 1116. The first electrode 1161 may be an electrode formed to supply holes to the light-emitting layer 1162. The first electrode 1161 may be formed of a transparent conductive material having a high work function. Here, the transparent conductive material may include indium tin oxide (ITO), indium zinc oxide (IZO), and indium tin zinc oxide (ITZO), but is not limited thereto. The first electrode 1161 may be formed of the same material as the data pad 1143 and the gate pad 1141 that are disposed on the planarization layer 1116, but is not limited thereto. In addition, when the stretchable display apparatus 1_2 is implemented in a top emission manner, the first electrode 1161 may further include a reflector. In addition, the first electrode 1161 may be formed of magnesium (Mg), calcium (Ca), aluminum (Al), silver (Ag), or an alloy thereof, which has a low work function and may reflect light emitted from the organic light-emitting layer 1162, but is not limited thereto.

The first electrode 1161 may be disposed to be spaced apart from each other in each sub-pixel and electrically connected to the thin film transistor 1150 through a contact hole of the planarization layer 1116. For example, FIG. 9 illustrates the first electrode 1161 electrically connected to the drain electrode 1154 of the thin film transistor 1150, but the first electrode 1161 may be electrically connected to the source electrode 1153.

A bank 1117 may be disposed on the first electrode 1161, the data pad 1143, the connection pad 1142, and the planarization layer 1116. The bank 1117 may be a component that distinguishes adjacent sub-pixels. The bank 1117 may be disposed to cover at least parts of both sides of the adjacent first electrode 1161 to expose a part of an upper surface of the first electrode 1161. The bank 1117 can solve a problem that an unintended sub-pixel emits light or is color-mixed by light emitting in a lateral direction of the first electrode 1161 due to the concentration of a current at an edge of the first electrode 1161. The bank 1117 may be formed of an acryl-based resin, a benzocyclobutene (BCB) resin, or a polyimide, but is not limited thereto.

The bank 1117 may include a contact hole connecting a second connection line 1182, which serves as a data line, to the data pad 1143, and a contact hole connecting a first connection line 1181, which serves as a gate line, to the connection pad 1142.

The light-emitting layer 1162 may be disposed on the first electrode 1161. The light-emitting layer 1162 may be formed to emit light. The light-emitting layer 1162 may include a light-emitting material, and the light-emitting material may include a phosphorescent material or a fluorescent material, but is not limited thereto.

The light-emitting layer 1162 may be formed as one light-emitting layer. As another example, the light-emitting layer 1162 may have a stack structure in which a plurality of light-emitting layers are stacked with a charge generation layer interposed therebetween. The light-emitting layer 1162 may further include at least one organic layer among a hole transporting layer, an electron transporting layer, a hole blocking layer, an electron blocking layer, a hole injecting layer, and an electron injecting layer, but is not limited thereto.

The second electrode 1163 may be disposed on the light-emitting layer 1162. The second electrode 1163 may supply electrons to the light-emitting layer 1162. The second electrode 1163 may be formed of a material having a different work function from the material forming the first electrode 1161, but is not limited thereto. The second electrode 1163 may be formed of, for example, an indium tin oxide (ITO), indium zinc oxide (IZO), indium tin zinc oxide (ITZO), zinc oxide (ZnO), or tin oxide (TO)-based transparent conductive oxide, or an ytterbium (Yb) alloy, but is not limited thereto. As another example, the second electrode 1163 may be formed of a metallic material.

When the stretchable display apparatus 1_2 is implemented in a bottom emission manner, the second electrode 1163 may further include a reflector.

In addition, the second electrode 1163 may be formed of magnesium (Mg), calcium (Ca), aluminum (Al), silver (Ag), or an alloy thereof, which has a low work function and may reflect light emitted from the organic light-emitting layer 1162, but is not limited thereto. The second electrode 1163 may be patterned and formed to overlap each of the fourth cover layers CW4 of the rigid area RA. For example, the second electrode 1163 may be formed in an area overlapping the fourth cover layer CW4 of the rigid area RA and may be disposed so as not to be formed in the soft area SA. Since the second electrode 1163 is formed of a material, such as a transparent conductive oxide, a transparent metallic material, or a reflective metallic material, when the second electrode 1163 is also formed in the area between the fourth cover layers CW4 in which the light-emitting element 1160 is disposed, for example, in the soft area SA, the second electrode 1163 can be damaged during the process of stretching the stretchable display apparatus 1_2. Accordingly, the second electrode 1163 may be formed to correspond to each of the fourth cover layers CW4 of the rigid area RA in a plan view. The second electrode 1163 may be formed to have an area that does not overlap an area in which the connection line 1180 is disposed in the area overlapping the fourth cover layer CW4 of the rigid area RA.

An encapsulation layer 1108 may be disposed on the light-emitting element 1160. The encapsulation layer 1108 may cover the light-emitting element 1160 and may be in contact with a part of the upper surface of the bank 1117 to encapsulate the light-emitting element 1160. Accordingly, the encapsulation layer 1108 can protect the light-emitting element 1160 from external moisture or air that may penetrate, or an external physical impact.

The encapsulation layer 1108 may cover each of the second electrodes 1163 patterned to overlap each of the fourth cover layers CW4 of the rigid area RA and may be formed in each of the fourth cover layers CW4. For example, the encapsulation layer 1108 may be disposed to cover one second electrode 1163 disposed on one fourth cover layer CW4, and the encapsulation layers 1108 respectively disposed on the fourth cover layers CW4 of the rigid area RA may be spaced apart from each other.

The encapsulation layer 1108 may be disposed in an area overlapping the fourth cover layer CW4 of the rigid area RA. Since the encapsulation layer 1108 may include an inorganic layer, the encapsulation layer 1108 can be easily damaged, such as cracks occurring during the process of stretching the stretchable display apparatus 1_2. For example, since the light-emitting clement 1160 is vulnerable to moisture or oxygen, when the encapsulation layer 1108 is damaged, the reliability of the light-emitting element 1160 can be reduced. Accordingly, in the stretchable display apparatus 1_2 according to the embodiment of the present disclosure, since the encapsulation layer 1108 is not formed in the soft area SA, even when the stretchable display apparatus 1_2 is deformed, such as bending, stretching, etc., it is possible to minimize damage to the encapsulation layer 1108.

As another example, as needed, the encapsulation layer 1108 may be formed entirely on the substrate 1110 including the rigid area RA and the soft area SA.

Comparing the stretchable display apparatus 1_2 according to the embodiment of the present disclosure with a flexible display apparatus, the stretchable display apparatus 1_2 may have a structure in which the rigid area RA which is relatively rigid of the fourth cover layer CW4 is disposed between the soft areas SA which are relatively soft of the fourth cover layer CW4. In addition, the second electrode 1163 and the encapsulation layer 1108 of the stretchable display apparatus 1_2 may be patterned and disposed to correspond to each of the plurality of fourth cover layers CW4 in the rigid area RA which is relatively rigid. For example, in the stretchable display apparatus 1_2 according to the embodiment of the present disclosure, when a user stretches or bends the stretchable display apparatus 1_2, the stretchable display apparatus 1_2 may have a structure that can be more easily deformed and a structure that can minimize damage to components of the stretchable display apparatus 1_2 during the process in which the stretchable display apparatus 1_2 is deformed.

Even in this case, since the display apparatus 1_2 may include a plurality of cover layers and back covers that have different moduli, it is possible to secure a sufficient stretch ration and smoothly stretch the display apparatus without damage to circuit elements of the display panel. Furthermore, it is possible to increase the life of the display apparatus 1_2, thereby reducing power consumption.

In addition, since various light-emitting elements of the display apparatus 1_2 may be applied according to a design, the design of the display apparatus 1_2 can be changed more smoothly according to the user's needs.

The display apparatus according to various embodiments of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an e-book, a portable multimedia player (PMP), a personal digital assistant (PDA), an MP3 player, a mobile medical device, a desktop PC, a laptop PC, a netbook computer, a workstation, a navigation system, a vehicle display apparatus, a theater display apparatus, a television, a wallpaper device, a signage device, a game device, a laptop computer, a monitor, a camera, a camcorder, a home appliances, etc.

A display apparatus according to various embodiments of the present disclosure may be described as follows.

According to embodiments of the present disclosure, there is provided a display apparatus including a panel support layer, a display panel disposed on the panel support layer, a panel cover layer disposed on the display panel, and a first cover layer disposed on the panel cover layer and having a greater modulus than the panel cover layer.

According to various embodiments of the present disclosure, the modulus of the panel cover layer and a modulus of the panel support layer may be the same.

According to various embodiments of the present disclosure, the modulus of the panel cover layer and a modulus of the panel support layer may range from 0.1 MPa to 1.5 MPa.

According to various embodiments of the present disclosure, the modulus of the first cover layer may range from 5 MPa to 7 MPa.

According to various embodiments of the present disclosure, a thickness of the first cover layer may be smaller than a thickness of the panel cover layer and a thickness of the panel support layer.

According to various embodiments of the present disclosure, the thickness of the first cover layer may range from 1 μm (micrometer) to 10 μm, and the thickness of the panel cover layer and the thickness of the panel support layer may range from 300 μm (micrometer) to 350 μm.

According to various embodiments of the present disclosure, the display apparatus may further include a second cover layer disposed between the first cover layer and the panel cover layer, in which a modulus of the second cover layer may be smaller than the modulus of the first cover layer and greater than the modulus of the panel cover layer.

According to various embodiments of the present disclosure, the modulus of the second cover layer may range from 3 MPa to 5 MPa.

According to various embodiments of the present disclosure, a thickness of the second cover layer may range from 300 μm (micrometer) to 400 μm.

According to various embodiments of the present disclosure, the display apparatus may further include a touch layer disposed between the second cover layer and the panel cover layer.

According to various embodiments of the present disclosure, the display apparatus may further include a back cover disposed below the panel support layer, in which a modulus of the back cover may be smaller than the modulus of the first cover layer and greater than the modulus of the panel cover layer.

According to various embodiments of the present disclosure, the display apparatus may further include a second cover layer disposed between the first cover layer and the panel cover layer, in which the modulus of the back cover may be the same as the modulus of the second cover layer.

According to various embodiments of the present disclosure, a thickness of the back cover may be the same as a thickness of the second cover layer.

According to various embodiments of the present disclosure, the display panel may include a transistor disposed on the panel support layer, a first pad electrically connected to the transistor, a light-emitting element electrically connected to the first pad and including a first electrode, a second electrode, and a light-emitting part, and a conductive adhesive member disposed between the first pad and the first electrode, in which the first pad and the first electrode may be electrically connected by the conductive adhesive member.

According to embodiments of the present disclosure, there is provided a display apparatus including a first cover layer, a second cover layer disposed on the first cover layer, a third cover layer disposed on the second cover layer, a display panel disposed on the third cover layer, and a fourth cover layer disposed on the display panel, in which a modulus of each of the first cover layer, the second cover layer, the third cover layer, and the fourth cover layer increases in a direction away from the display panel.

According to various embodiments of the present disclosure, the modulus of the third cover layer and the modulus of the fourth cover layer may be the same.

According to various embodiments of the present disclosure, a thickness of the third cover layer and a thickness of the fourth cover layer may be the same.

According to various embodiments of the present disclosure, the display apparatus may further include a touch layer disposed between the third cover layer and the second cover layer.

According to various embodiments of the present disclosure, the modulus of the second cover layer may be smaller than the modulus of the first cover layer and greater than the modulus of the third cover layer.

According to various embodiments of the present disclosure, the display apparatus may further include a back cover wherein the fourth cover layer is disposed between the display panel and the back cover, in which a modulus of the back cover may be the same as the modulus of the second cover layer.

Although the embodiments have been described above with reference to the accompanying drawings, those skilled in the art to which the present disclosure pertains will be able to understand that the above-described technical configuration can be carried out in other specific forms without changing the technical spirit or essential features thereof. Accordingly, it should be understood that the above-described embodiments are illustrative and not restrictive in all respects. In addition, the scope of the embodiments is determined by the appended claims rather than detailed description. In addition, the meaning and scope of the claims and all changed or modified forms derived from the equivalent concept thereof should be construed as being included in the scope of the embodiments.

### DESCRIPTION OF REFERENCE NUMERALS

1: display apparatus
10: display panel
CW1: first cover layer
CW2: second cover layer
CW3: third cover layer
CW4: fourth cover layer
20: touch layer
30: back cover

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a panel support layer;
a display panel disposed on the panel support layer;
a panel cover layer disposed on the display panel; and
a first cover layer disposed on the panel cover layer and having a greater modulus than the panel cover layer.

2. The display apparatus of claim 1, wherein the modulus of the panel cover layer and a modulus of the panel support layer are the same.

3. The display apparatus of claim 1, wherein the modulus of the panel cover layer and the modulus of the panel support layer range from 0.1 MPa to 1.5 MPa.

4. The display apparatus of claim 1, wherein the modulus of the first cover layer ranges from 5 MPa to 7 MPa.

5. The display apparatus of claim 1, wherein a thickness of the first cover layer is smaller than a thickness of the panel cover layer and a thickness of the panel support layer.

6. The display apparatus of claim 1, wherein the thickness of the first cover layer ranges from 1 μm to 10 μm, and wherein the thickness of the panel cover layer and the thickness of the panel support layer range from 300 μm to 350 μm.

7. The display apparatus of claim 1, further comprising a second cover layer disposed between the first cover layer and the panel cover layer,
wherein a modulus of the second cover layer is smaller than the modulus of the first cover layer and greater than the modulus of the panel cover layer.

8. The display apparatus of claim 7, wherein the modulus of the second cover layer ranges from 3 MPa to 5 MPa.

9. The display apparatus of claim 7, wherein a thickness of the second cover layer ranges from 300 μm to 400 μm.

10. The display apparatus of claim 7, further comprising a touch layer disposed between the second cover layer and the panel cover layer.

11. The display apparatus of claim 1, further comprising a back cover disposed below the panel support layer,
wherein a modulus of the back cover is smaller than the modulus of the first cover layer, and
wherein the modulus of the back cover greater than the modulus of the panel cover layer.

12. The display apparatus of claim 11, further comprising a second cover layer disposed between the first cover layer and the panel cover layer,
wherein the modulus of the back cover is the same as the modulus of the second cover layer.

13. The display apparatus of claim 12, wherein a thickness of the back cover is the same as a thickness of the second cover layer.

14. The display apparatus of claim 1, wherein the display panel includes:
a transistor disposed on the panel support layer;
a first pad electrically connected to the transistor;
a light-emitting element electrically connected to the first pad, the light-emitting element including a first electrode, a second electrode, and a light-emitting part; and
a conductive adhesive member disposed between the first pad and the first electrode, and
wherein the first pad and the first electrode are electrically connected by the conductive adhesive member.

15. A display apparatus comprising:
a first cover layer;
a second cover layer disposed on the first cover layer;
a third cover layer formed on the second cover layer;
a display panel disposed on the third cover layer; and
a fourth cover layer disposed on the display panel,
wherein a modulus of each of the first cover layer, the second cover layer, the third cover layer, and the fourth cover layer increases in a direction away from the display panel.

16. The display apparatus of claim 15, wherein the modulus of the third cover layer and the modulus of the fourth cover layer are the same.

17. The display apparatus of claim 15, wherein a thickness of the third cover layer and a thickness of the fourth cover layer are the same.

18. The display apparatus of claim 15, further comprising a touch layer disposed between the third cover layer and the second cover layer.

19. The display apparatus of claim 15, wherein the modulus of the second cover layer is smaller than the modulus of the first cover layer and greater than the modulus of the third cover layer.

20. The display apparatus of claim 15, further comprising a back cover,
wherein the fourth cover layer is disposed between the display panel and the back cover, and
wherein the modulus of the back cover is the same as the modulus of the second cover layer.
